(19) United States
(12) Patent Application Publication
(10) Pub. No.: US 2014/0376736 A1
(43) Pub. Date: Dec. 25, 2014

(54) CONTROL CIRCUIT FOR CONTROLLING AUDIO SIGNAL OUTPUT OF EARPHONE

(71) Applicant: Chiun Mai Communication Systems, Inc., New Taipei (TW)

(72) Inventor: CHENG-PING LIU, New Taipei (TW)

(73) Assignee: Chiun Mai Communication Systems, Inc., New Taipei (TW)

(21) Appl. No.: 14/014,333

(22) Filed: Aug. 29, 2013

(30) Foreign Application Priority Data
Jun. 21, 2013 (TW) 102122070

(51) Int. Cl. H03G 3/20; H04R 1/10

(52) U.S. Cl. CPC H03G 3/20; H04R 1/1091
USPC 381/74

(57) ABSTRACT

A control circuit for audio signal outputting of an earphone includes a central processing unit (CPU), an audio codec, an amplifier, and a detecting circuit. The audio codec receives audio signals from the CPU, and decodes the audio signals. The amplifier receives the decoded audio signals from the audio codec, amplifies the decoded audio signals, and outputs the amplified audio signals to the earphone. The CPU controls the detecting circuit to detect an impedance of the earphone, and controls the amplifier to adjust a volume of the audio signal output from the earphone according to the detected impedance of the earphone.

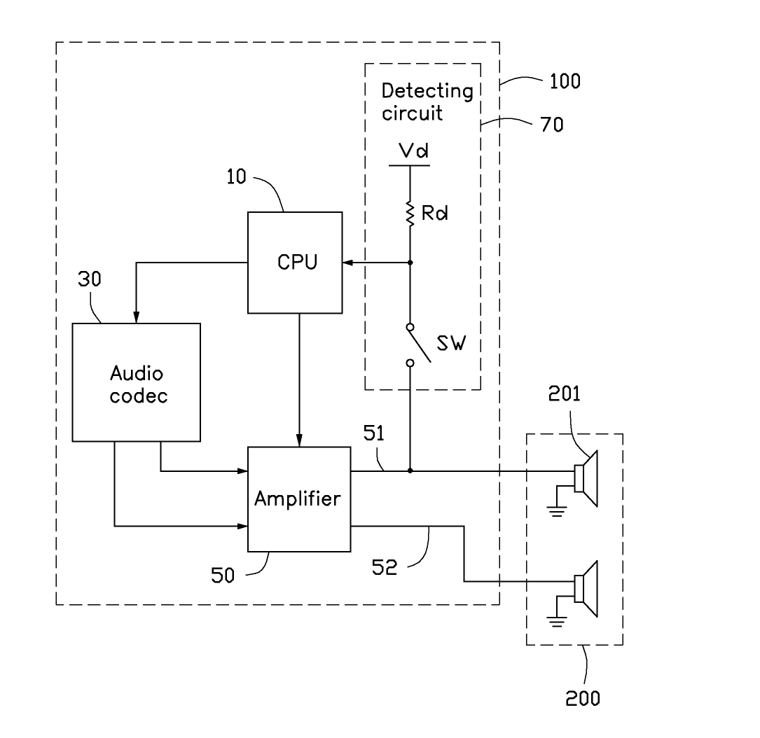

### BACKGROUND

1. Technical Field

The disclosure generally relates to control circuits for earphones, and particularly to a control circuit which automatically adjusts volume of audio output by earphones according an impedance of the earphones.

2. Description of Related Art

A portable electronic device such as a mobile phone commonly employs earphones having an impedance of 16Ω or 32Ω. Output of the earphone usually cannot be greater than a regulated sound pressure (such as EN50332-1). A voltage corresponding to the earphones having an impedance of 16Ω or 32Ω is relatively small. Therefore, if earphones having greater impedance are inserted into the portable electronic device, the earphones may not work properly.

Therefore, there is room for improvement within the art.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the disclosure.

The drawing is a circuit diagram of a control circuit for controlling audio signal output by earphones, according to an exemplary embodiment of the disclosure.

### DETAILED DESCRIPTION

The drawing is a circuit diagram of a control circuit 100 for controlling audio signal output of earphones 200, according to an exemplary embodiment of the disclosure. The control circuit 100 is used in a portable electronic device such as a mobile phone. When the earphones 200 are connected to the electronic device, the control circuit 100 controls volume of audio signals of the earphone 200.

The control circuit 100 includes a central processing unit (CPU) 10, an audio codec 30, an amplifier 50, and a detecting circuit 70. The CPU 10, the audio codec 30, and the amplifier 50 are orderly connected. The CPU 10 is also electronically connected to the amplifier 50 and the detecting circuit 70.

The CPU 10 transmits audio signals stored in the portable electronic device or received from other portable electronic devices to the audio codec 30. The audio codec 30 decodes the audio signals and transmits the decoded audio signals to the amplifier 50. The amplifier 50 amplifies the decoded audio signals and transmits the amplified audio signals to the earphones 200. In this exemplary embodiment, the earphones 200 include two built-in speakers 201. The amplifier 50 is electronically connected to the two speakers 201 by a left channel 51 and a right channel 52 respectively to output the amplified audio signals by the speakers 201.

The detecting circuit 70 includes a detecting resistor Rd and a switch SW. A first end of the detecting resistor Rd is electronically connected to a power supply Vd. A second end of the detecting resistor Rd is electronically connected to the CPU 10, and also connected to the left channel 51 by the switch SW.

In an initial state, the switch SW is turned on. When the earphones 200 are inserted into the portable electronic device, the detecting resistor Rd is electronically connected to the left channel 51, forms a detecting loop with one of the speakers 201 corresponding to the left channel 51. The CPU 10 detects a voltage of the one of the speakers 201 and obtains an impedance of the one of the speakers 201 according to a formula that Rimp=VimpxR/(Vd−Vimp), where, Vimp represents the detected voltage of the one of the speakers 201, R represents a resistance of the detecting resistor Rd, Vd represents a voltage of the power supply, Rimp represents the impedance of the one of the speakers 201. Ordinarily, the other one of the speakers 201 corresponding to the right channel 52 will have the same impedance as the one of the speakers 201 corresponding to the left channel 51. Therefore, the CPU 10 can obtain the overall impedance of the earphones 200 by doubling the impedance of the one of the speakers 201 corresponding to the left channel 51.

Before the earphones 200 output the audio signals, the CPU 10 controls the switch SW to turn off so that the detecting circuit 70 can avoid interference with the audio signals output by the earphones 200. Therefore, during the process of detecting the impedance of the earphones 200, the left channel 51 and the right channel 52 continue to output the amplified audio signals to the speakers 201.

The CPU 10 detects the impedance of the earphone 200 through the detecting circuit 70 and controls the volume of the audio signals output from the earphones 200 by changing the amplification of the amplified audio signals from the amplifier 50 or controlling a signal intensity of the decoded audio signals output from the audio codec 30 according to the detected impedance of the earphones 200.

The control circuit 100 controls the detecting circuit 70 to detect the impedance of the earphones 200 and adjusts the volume of the earphones 200 accordingly so that even earphones with greater impedance will work properly in the electronic device.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A control circuit for controlling audio signal output of an earphone, comprising:
a central processing unit (CPU);
an audio codec receiving audio signals from the CPU and decoding the audio signals;
an amplifier receiving the decoded audio signals from the audio codec, amplifying the decoded audio signals, and outputting the amplified audio signals to the earphone; and
a detecting circuit; wherein the CPU controls the detecting circuit to detect an impedance of the earphone, and controls the amplifier to adjust a volume of the audio signal output from the earphone according to the detected impedance of the earphone.

2. The control circuit of claim 1, wherein the detecting circuit comprises a detecting resistor and a switch, wherein a first end of the detecting resistor is electronically connected to a power supply and a second end of the detecting resistor is electronically connected to the CPU and is also connected between the amplifier and the earphone by the switch.

3. The control circuit of claim 2, wherein in an initial state, the switch is turned on; when the CPU detects the earphone is connected to the amplifier, the CPU detects the impedance of the earphone by the detecting circuit; before the earphones output the audio signals, the CPU controls the switch to turn off.

4. The control circuit of claim 1, wherein the earphone comprises two speakers electronically connected to the amplifier by a left channel and a right channel, respectively; the second end of the detecting resistor connects to one of the left channel and the right channel, when the switch is turned on, the detecting resistor is electronically connected to one of the left channel and the right channel, and forms a detecting loop with one of the left channel and the right channel so that the CPU detects a voltage of the CPU and obtains the impedance of the earphone according to the detected voltage.

5. The control circuit of claim 4, wherein the CPU detects the voltage, and calculates an impedance of the one of speakers according to a formula: Rimp=VimpxR/(Vd−Vimp) to obtain the impedance of the earphone, wherein Vimp represents the detected voltage of the one of speakers 201, R represents a resistance of the detecting resistor Rd, Vd represents a voltage of the power supply Vd, and Rimp represents the impedance of the one of speakers.

6. The control circuit of claim 1, wherein the CPU controls the volume of the audio signals output from the earphone by changing an amplification of the amplified audio signals from the amplifier according to the detected impedance of the earphone.

7. The control circuit of claim 1, wherein the CPU controls the volume of the audio signals output from the earphone by controlling a signal intensity of the decoded audio signals outputted from the audio codec according to the detected impedance of the earphones.

8. A control circuit for controlling audio signal outputting of an earphone, comprising:
a central processing unit (CPU);
an audio codec receiving audio signals from the CPU, and decoding the audio signals;
an amplifier receiving the decoded audio signals from the audio codec, amplifying the decoded audio signals, and output the amplified audio signals to the earphone; and
a detecting circuit, the detecting circuit comprising a detecting resistor and a switch, wherein a first end of the detecting resistor is electronically connected to a power supply; a second end of the detecting resistor is electronically connected to the CPU and also connected between the amplifier and the earphone by the switch, when the switch is turned on, and a detecting loop is formed with the earphone so that the CPU detects the impedance of the earphone according to the detecting loop.

9. The control circuit of claim 8, wherein in an initial state, the switch is turned on; when the CPU detects the earphone is connected to the amplifier, the CPU detects the impedance of the earphone by the detecting loop; before the earphone outputs the audio signals, the CPU controls the switch to turn off.

10. The control circuit of claim 8, wherein the earphone comprises two speakers electronically connected to the amplifier by a left channel and a right channel, respectively; the second end of the detecting resistor connects to one of the left channel and the right channel, when the switch is turned on, the detecting resistor is electronically connected to one of the left channel and the right channel, and forms the detecting loop with the one of the left channel and the right channel.

11. The control circuit of claim 10, wherein the CPU detects the voltage of the one of the speakers, and calculates an impedance of the one of speakers according to a formula: Rimp=VimpxR/(Vd−Vimp) to obtain the impedance of the earphones, wherein; Vimp represents the detected voltage of the one of speakers 201, R represents a resistance of the detecting resistor Rd, Vd represents a voltage of the power supply Vd, and Rimp represents the impedance of the one of speakers.

12. The control circuit of claim 8, wherein the CPU controls the volume of the audio signals output from the earphone by changing an amplify of the amplified audio signals from the amplifier according to the detected impedance of the earphone.

13. The control circuit of claim 8, wherein the CPU controls the volume of the audio signals output from the earphone by controlling a signal intensity of the decoded audio signals outputted from the audio codec according to the detected impedance of the earphone.
